(19) United States
(12) Patent Application Publication
(10) Pub. No.: US 2007/0264581 A1
(43) Pub. Date: Nov. 15, 2007

(54) Patterning masks and methods

(76) Inventor: Christian J. Schwarz, Albany, NY (US)

Correspondence Address: SLATER & MATSIL LLP, 17950 PRESTON ROAD, SUITE 1000, DALLAS, TX, 75252, US

(21) Appl. No.: 11/430,607

(22) Filed: May 9, 2006

(51) Int. Cl. G03C 5/00; G03F 1/00

(52) U.S. Cl. 430/5; 430/394

(57) ABSTRACT

Patterning masks and methods for lithography are disclosed. A preferred embodiment includes a lithography mask comprising a pattern for at least one feature and at least one polarizing element.

### TECHNICAL FIELD

The present invention relates generally to the fabrication of semiconductor devices, and more particularly to lithography masks for patterning material layers of semiconductor and other devices.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (ICs). There may be a plurality of transistors, memory devices, switches, conductive lines, diodes, capacitors, logic circuits, and other electronic components formed on a single die or chip, for example.

Optical photolithography involves projecting or transmitting light through a pattern comprised of optically opaque areas and optically clear or transparent areas on a mask or reticle. For many years in the semiconductor industry, optical lithography techniques such as contact printing, proximity printing, and projection printing have been used to pattern material layers of integrated circuits. Lens projection systems and transmission lithography masks are used for patterning, wherein light is passed through the lithography mask to impinge upon a photosensitive material layer disposed on a semiconductor wafer or workpiece. After development, the photosensitive material layer is then used as a mask to pattern an underlying material layer. The patterned material layers comprise electronic components of the semiconductor device.

There is a trend in the semiconductor industry towards scaling down the size of integrated circuits, to meet the demands of increased performance and smaller device size, leading to more cost efficient production. As features of semiconductor devices become smaller, it becomes more difficult to pattern the various material layers because of diffraction and other effects that occur during the lithography process.

Lithography techniques such as immersion lithography and EUV lithography, as examples, are under development to address the lithography challenges of decreased feature sizes. However, incorrect dimensioning, for example, “line shortening” or line width variation of features, particularly for features comprising critical dimensions (CD's), still poses a problem for smaller features, often only in one direction of a wafer.

A recent development in lithography is the use of polarized light for the exposure process. However, polarized light tends to work well for patterning features with certain orientations and not as well for features with other orientations.

Thus, what are needed in the art are improved lithography masks and methods for patterning material layers of semiconductor devices.

### SUMMARY OF THE INVENTION

These and other problems are generally solved or circumvented, and technical advantages are generally achieved, by preferred embodiments of the present invention, which provide novel lithography masks and methods for patterning material layers of semiconductor devices.

In accordance with a preferred embodiment of the present invention, a lithography mask comprises a pattern for at least one feature and at least one polarizing element.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a perspective view of a prior art lithography mask, illustrating that vertical features and horizontal features require different polarizations of light to effectively transfer a pattern to a semiconductor device;

FIGS. 2a and 2b illustrate the differences in the influence on contrast of polarization types when used for imaging;

FIG. 3 shows a lithography system in accordance with a preferred embodiment of the present invention;

FIG. 4 illustrates a top view of a novel lithography mask in accordance with a preferred embodiment of the present invention, wherein patterns for features include polarizing gratings or apertures;

FIG. 5 shows a top view of a semiconductor device patterned using the lithography mask shown in FIG. 4;

FIG. 6 illustrates a top view of a lithography mask in accordance with another preferred embodiment of the present invention, wherein polarizing gratings or apertures are disposed proximate the patterns for features;

FIGS. 7 and 8 show cross-sectional views of the lithography mask shown in FIG. 6;

FIG. 9 shows a top view of a lithography mask in accordance with yet another preferred embodiment of the present invention, wherein the mask includes a polarizing material;

FIG. 10 shows a perspective view of the mask shown in FIG. 9, wherein the polarizing material is disposed locally proximate patterns for features;

FIG. 11 illustrates a perspective view of a lithography mask in accordance with another embodiment of the present invention, wherein a polarizing material is disposed globally on the mask;

FIG. 12 shows a perspective view of a pellicle adapted to protect a lithography mask in accordance with an embodiment of the present invention, wherein the pellicle includes polarizing elements;

FIG. 13 shows a lithography mask attached to the pellicle illustrated in FIG. 12, wherein the polarizing elements are disposed proximate patterns of features on the mask;

FIG. 14 shows a cross-sectional view of a semiconductor device with a layer of photosensitive material disposed thereon that has been patterned using one of the novel lithography masks described herein;

FIG. 15 shows the semiconductor device of FIG. 14 after the layer of photosensitive material has been used to pattern a material layer of the semiconductor device;

FIG. 16 illustrates a top view of a lithography mask in accordance with another embodiment of the present invention;

FIG. 17 shows a perspective view of the lithography mask shown in FIG. 4, illustrating the effect of the novel lithography mask on energy that is directed towards the lithography mask;

FIG. 18a shows a top view of a lithography mask in accordance with an embodiment of the present invention implemented in a binary bright field mask;

FIG. 18b shows a cross-sectional view of the lithography mask of FIG. 18a;

FIG. 18c shows a cross-sectional view of a semiconductor device that has been patterned using the mask shown in FIGS. 18a and 18b;

FIG. 19a shows a top view of a lithography mask in accordance with an embodiment of the present invention implemented in a binary dark field mask;

FIG. 19b shows a cross-sectional view of the lithography mask of FIG. 19a;

FIG. 19c shows a cross-sectional view of a semiconductor device that has been patterned using the mask shown in FIGS. 19a and 19b;

FIG. 20a shows a top view of a lithography mask in accordance with an embodiment of the present invention implemented in a phase shifting bright field mask;

FIG. 20b shows a cross-sectional view of the lithography mask of FIG. 18a;

FIG. 20c shows a cross-sectional view of a semiconductor device that has been patterned using the mask shown in FIGS. 20a and 20b;

FIG. 21a shows a top view of a lithography mask in accordance with an embodiment of the present invention implemented in a phase shifting dark field mask;

FIG. 21b shows a cross-sectional view of the lithography mask of FIG. 21a; and

FIG. 21c shows a cross-sectional view of a semiconductor device that has been patterned using the mask shown in FIGS. 21a and 21b.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that embodiments of the present invention provide many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely implemented in manufacturing processes used to fabricate semiconductor devices. Embodiments of the invention may also be applied, however, to other applications where material layers are patterned using lithography or a direct patterning method, such as in the patterning of liquid crystal displays (LCD's) and other applications in the telecommunication, consumer electronics and optical industries, as examples.

As feature sizes of semiconductor devices continue to shrink, it becomes exceedingly difficult to image a set of different features and feature sizes on a material layer. It is usually desirable for all devices of the same type which are designed with the same dimensions to exhibit the same electrical performance across a surface of a wafer. However, as feature sizes become smaller, it is often difficult to form vertical and horizontal lines having the same lengths and widths, for example, which causes differences in electrical performance of devices.

The terms “horizontal” and “vertical” are referred to herein regarding the orientation of features formed on a planar surface of a workpiece or wafer, wherein the term “horizontal” refers to a first direction on the planar surface of the wafer, and wherein the term “vertical” refers to a direction on the planar surface of the wafer substantially perpendicular to the horizontal direction. In some embodiments, for example, the term “horizontal” direction on a wafer is defined with respect to movement of a lithography mask and wafer stage during a scanning process, e.g., a direction on the planar surface of the wafer parallel to the direction of the scanning, and wherein the term “vertical” refers to a direction on the planar surface of the wafer that is substantially perpendicular to the scanning direction.

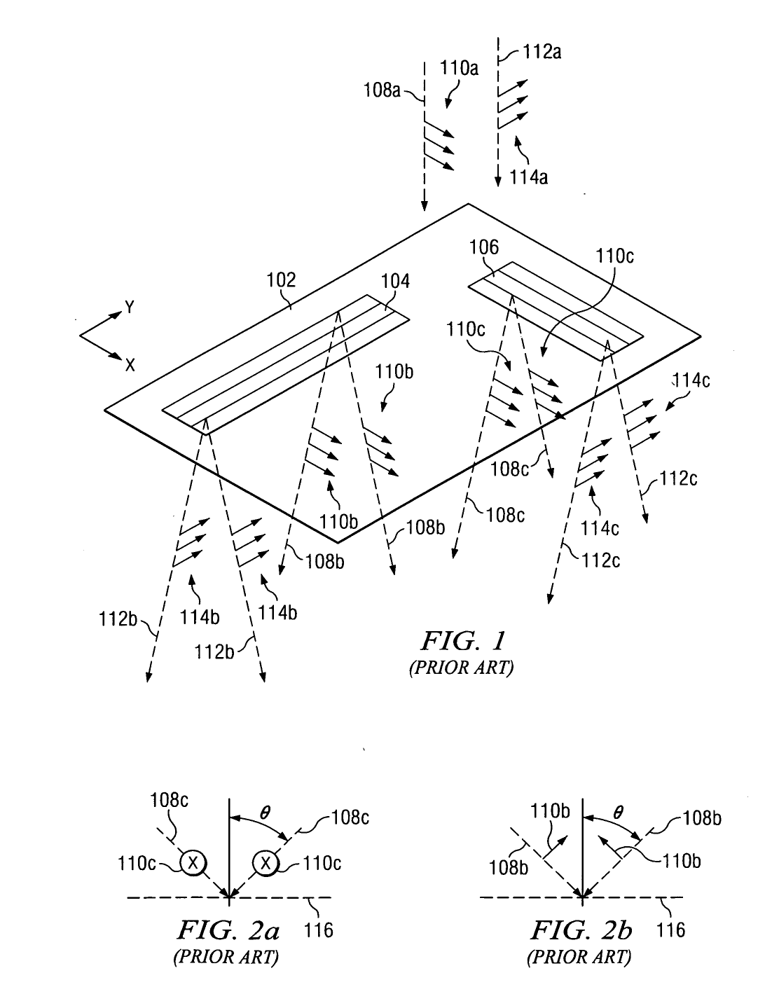

In many semiconductor designs, such as CMOS transistors, devices are laid out or positioned in two substantially orthogonal directions, e.g., on an x axis and a y axis. FIG. 1 illustrates a top view of a prior art lithography mask 102 for use in patterning a semiconductor device, wherein patterns for vertically oriented features 104 are positioned lengthwise along the y axis perpendicular to patterns for horizontally oriented features 106 positioned lengthwise along the x axis. The patterns for features 104 and 106 may comprise the patterns for gates of transistors, for example, or other features of a semiconductor device.

Features of a semiconductor device are typically formed by depositing a layer of photosensitive material over a workpiece, and exposing the layer of photosensitive material using a lithography mask, e.g., in a horizontal scanning direction along the x axis. The layer of photosensitive material is then developed and used as a mask to pattern a material layer of the workpiece, forming features within the material layer of the semiconductor device.

In some lithography methods, polarized light is used to expose a layer of photosensitive material using a mask 102 such as the one shown in FIG. 1. Polarized light comprises an electromagnetic wave propagating in a direction (e.g., shown at 108a or 112a) and having polarization states 110a and 114a, respectively, polarized in the x and y directions, respectively, at orthogonal directions perpendicular to the wave propagation direction 108a or 112a.

When the polarized light 108a arrives at an image plane 116, as shown in FIGS. 2a and 2b, transverse electric and magnetic fields are formed. FIGS. 2a and 2b illustrate the influence of polarization on imaging contrast for polarized light 108a shown in FIG. 1. In the image plane 116, e.g., wherein the light 108a coming from the mask 102, shown at 108c and 108b in FIGS. 2a and 2b, respectively, a transverse electric (TE) wave 110c exists as shown in FIG. 2a and a transverse magnetic (TM) wave 110b exists, as shown in FIG. 2b. Because the light 108a is polarized in the x direction or state 110a, a TE wave 110c is formed in the image plane 116 of the horizontal feature 106, and a TM wave 110b is formed in the image plane 116 of the vertical feature 104.

The arrows 108c and 108b indicate the direction of the polarized light wave propagation. The TE wave is indicated at 110c in and out of the paper in FIG. 2a and the TM wave is indicated at 114a perpendicular to the propagation direction parallel to the paper in the image plane 116. The incident angle of the propagation direction is shown at θ, e.g., in the image plane 116, and the incident angle θ may vary as a result or function of the size of the patterns for the features 104 and 106.

For a lithography projection system with a demagnification factor of 4, the sine of θ is equal to the ratio of the wavelength of the light over the line width (CD) in a periodic array of features, for example. While the contrast of the TE wave 110c is independent of the incident angle θ, the contrast of the TM wave 110b is a function of the cosine of 2θ. For periodic features having dimensions of around 273 nm on the mask 102, using a TM wave 110b results in effectively no contrast or image resolved on an object, for example.

Thus, it is desirable for a TE wave 110c to be used for exposure of a horizontal feature 106, rather than a TM wave 110b, which is achieved by using a light beam 108a having an x polarization state 110a, rather than using a light beam 112a having a y polarization state 114a, which would result in a TM wave 114c, as shown at 112c in FIG. 1.

To image smaller features on semiconductor devices, the industry is moving towards the use of higher numerical aperture (NA) tools, e.g., having larger lenses, which result in larger angles in the imaging plane (e.g., on a semiconductor wafer) and also larger angles θ in the object plane on the mask. To print smaller features, larger angles of illumination (e.g., of the energy used for exposure) are needed, for example. The closer the angle θ is to 45 degrees, the more critical the polarization is in the illuminator of the lithography system, for example.

If polarized light is used in an exposure process, the polarized light is used to globally illuminate the mask 102 in a single direction 108a or 112a. Incoming light 108a polarized along x (e.g., at 110a) and incoming light 112a is polarized along y (e.g., at 114a), as shown in FIG. 1. Horizontal and vertical features 104 and 106 tend to scatter light at both types of polarization, as shown in FIG. 1 at 108b and 112b for the vertical features 104 and at 108c and 112c for the horizontal features 106. However, imaging using only one type of polarization 108a or 112a is preferred to achieve the optimum contrast, depending on the orientation of the features 104 or 106. An exposure process that uses only one type of polarized light 108a or 112a results in a global polarization of the mask 102 which is only effective for one type of feature 104 or 106.

For example, for a horizontal feature 106, an exposure process using polarized light 108a in an x direction 110a is preferred, because light 108c that passes through the mask 102 is polarized in the x direction, as shown at 110c, forming a TE wave 110c in the image plane 116 on the mask 102, as shown in FIG. 2a. However, an exposure process using polarized light 112a in the y direction 114a would result in poor contrast and poor resolution of the horizontal features formed on a semiconductor device, as shown at 112c polarized in the y direction, because a TM wave 114c is formed in the image plane 116 on the mask 102.

Likewise, for a vertical feature 104, an exposure process using polarized light 112a in a y direction 114a is preferred, because light 112b passed through the mask is polarized in the y direction, as shown at 114b, which results in a TE wave 114b being formed in the image plane on the mask. An exposure process using polarized light 108a in the x direction 110a would result in poor contrast and poor resolution of the vertical features formed on a semiconductor device, as shown at 108b polarized in the x direction, because a TM wave 110b is formed in the image plane 116 on the mask 102, as shown in FIG. 2b.

In general, polarized light can enhance the imaging process in lithography in some applications, but the direction of polarization best suited for some features (e.g., a horizontal feature 106) is not necessarily best suited for other features (e.g., a vertical feature 104). Thus, a global definition of the polarizing state of the illuminating light is not sufficient for the optimum imaging performance in some lithography processes.

In many applications, it is desirable for horizontal features formed on a semiconductor device to comprise a length in a horizontal direction that is substantially equal to the length of features in a vertical direction of the workpiece. It is also desirable for the horizontal features to comprise a width in a vertical direction of the workpiece that is substantially equal to the width of the vertical features in the horizontal direction of the workpiece. For example, if features comprise the same dimension as the dimensions of other features, then devices formed from the features will comprise the same operating parameters and electrical characteristics. If the features comprise transistor gates, for example, the widths of the gates largely impact the operating parameters of the transistors, e.g., the current and voltage. The widths of transistor gates are often referred to in the art as “gate lengths,” for example.

However, due to the use of polarized light in the exposure process, features in a horizontal orientation may comprise different dimensions than features in a vertical orientation. In particular, if polarized light 108a is used in the exposure process, then vertical features formed on a semiconductor device may have a decreased width compared to the width of horizontal features, for example. Features comprising different dimensions in some semiconductor applications are disadvantageous because devices formed have non-uniform performance and operating characteristics, resulting in decreased and unpredictable device performance, decreased yields, and increased overall manufacturing costs, for example.

To alleviate this problem, a double exposure process is sometimes used to form horizontal features and vertical features, using a first polarized light and a second polarized light polarized differently than the first polarized light. However, a double exposure process requires two masks and two exposure processes, which is costly and time-consuming.

Another proposed method is the use of a polarizing member, as described in U.S. Pat. No. 5,933,219 issued to Unno on Aug. 3, 1999, entitled, “Projection Exposure Apparatus and Device Manufacturing Method Capable of Controlling Polarization Direction,” which is hereby incorporated herein by reference. The polarizing member has different polarizing areas that are placed along the optical axis to change the polarization for horizontal and vertical features. However, the polarizing member requires the use of a controller that moves the polarizing member, and thus several additional components in a lithography system are required. Multiple scans across an area of a semiconductor device are required to expose a single chip, and the polarization alteration is limited to lengthwise-extending regions on a chip.

Thus, what are needed in the art are improved lithography masks, systems, and patterning methods, in which the polarization of light is controlled locally for features or groups of features of a lithography mask.

Embodiments of the present invention achieve technical advantages by providing novel lithography masks and methods, wherein portions of a lithography mask are polarized locally or globally, improving the resolution of features of semiconductor devices patterned by the novel lithography masks. Portions, e.g., patterns of some features, of the novel lithography masks are polarization dependent, for example, to be described further herein.

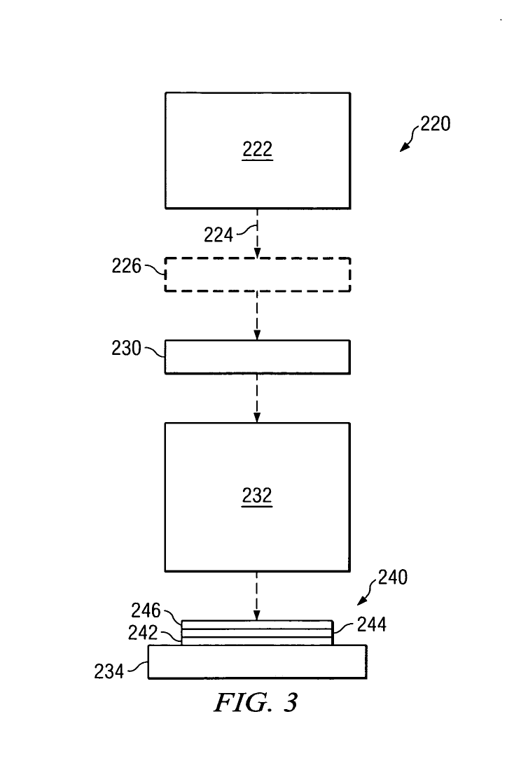

FIG. 3 shows a lithography system 220 in accordance with a preferred embodiment of the present invention. The lithography system 220 includes a support or stage 234 for a semiconductor device 240 or workpiece and a projection lens system 232 disposed proximate the semiconductor device support 234, as shown. The projection lens system 232 may include a plurality of lenses, e.g., not shown, and may include a fluid disposed between the semiconductor device 240 mounted on the support 234 and a last lens of the projection lens system 232, e.g., in an immersion lithography system, not shown. An illuminator 222 comprising an energy source is disposed proximate the projection lens system 232.

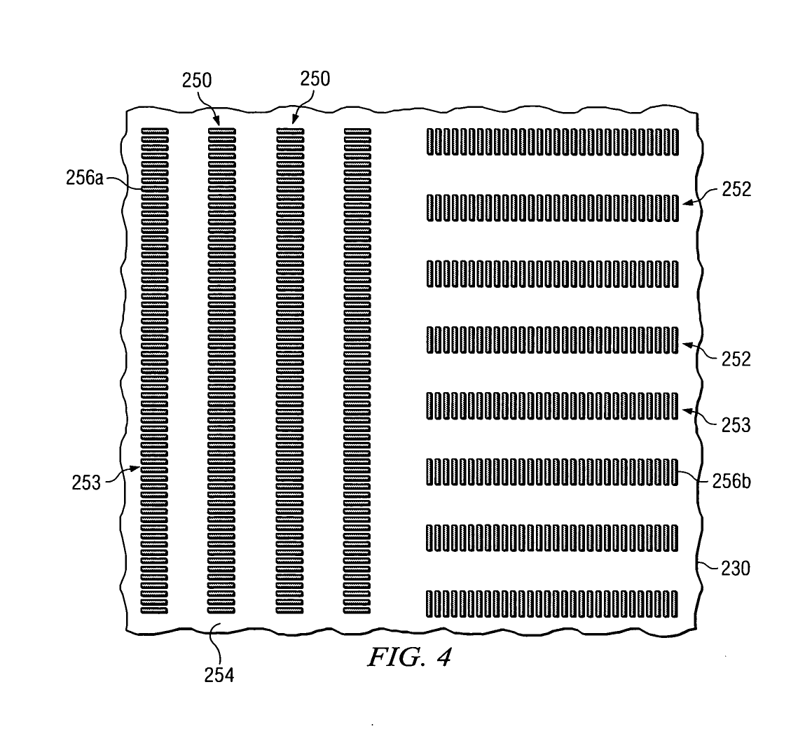

A novel lithography mask 230 of embodiments of the present invention is disposed between the projection lens system 232 and the illuminator 222. The lithography mask 230 may comprise one mask in a mask set, not shown. The lithography mask 230 preferably includes at least one polarization element (see 256a and 256b of FIG. 4, for example) adapted to polarize energy 224 (which may comprise light or radiation, as examples, although other types of energy 224 may also be used) directed at the lithography mask 230 from the illuminator 222 to a predetermined type of polarization towards the support 234 for the semiconductor device.

In some embodiments, an optional polarizer 226, shown in phantom in FIG. 3, may be disposed between the illuminator 222 and the lithography mask 230. The at least one polarization element of the lithography mask 230 may be disposed on a first side of the lithography mask 230 facing the illuminator 222, or the at least one polarization element may be disposed on a second side of the lithography mask 230 facing the projection lens system 232, for example, to be described further herein.

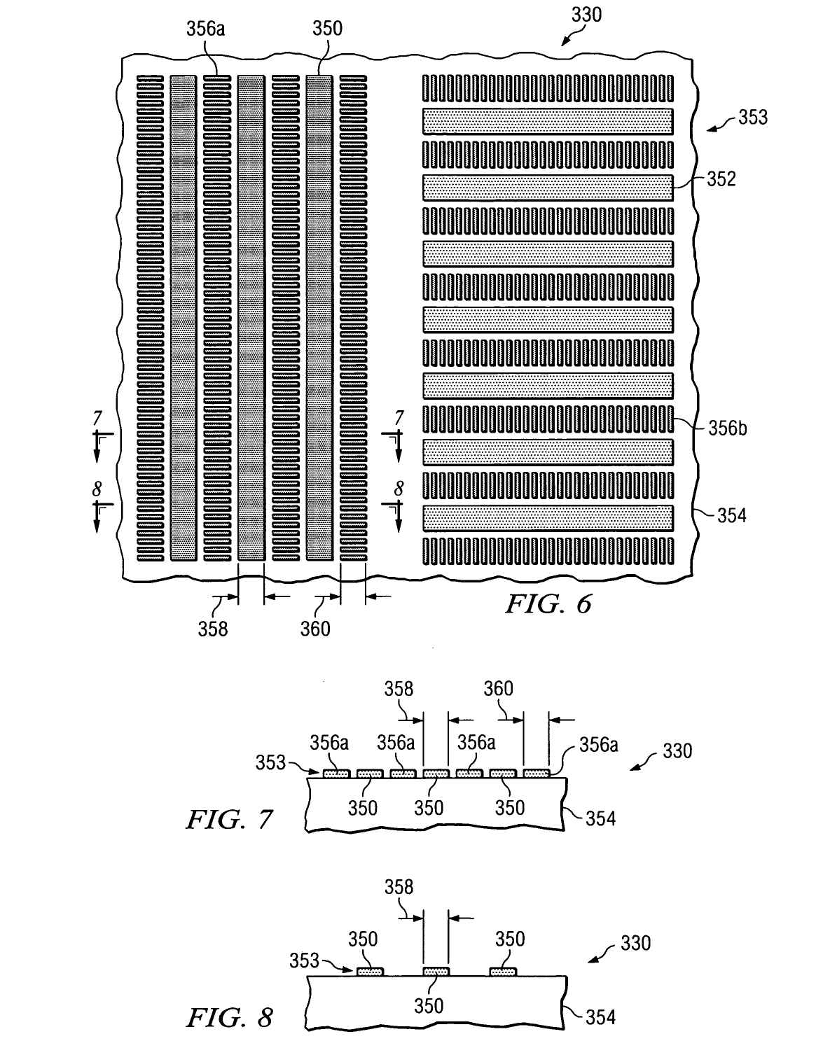

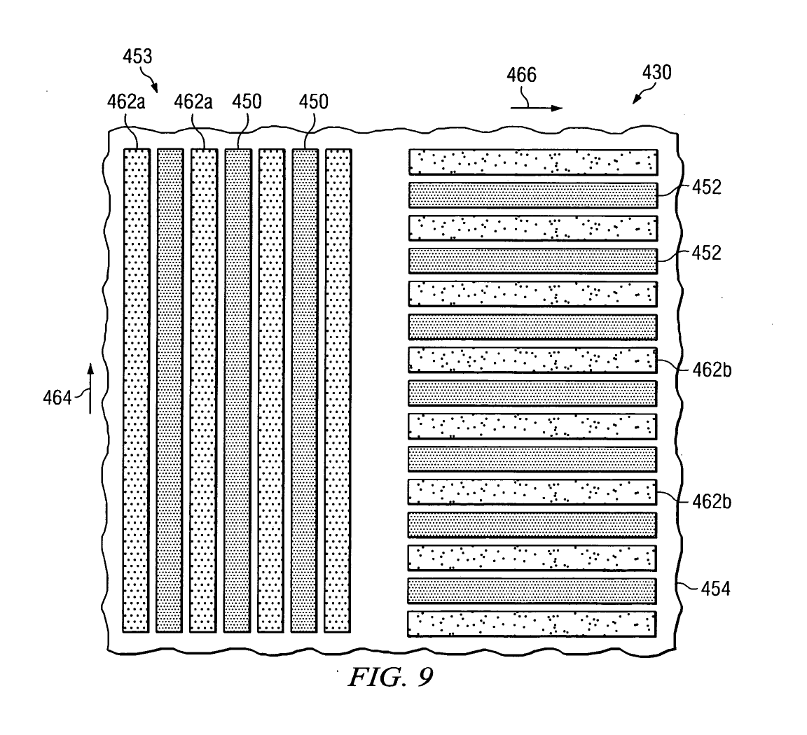

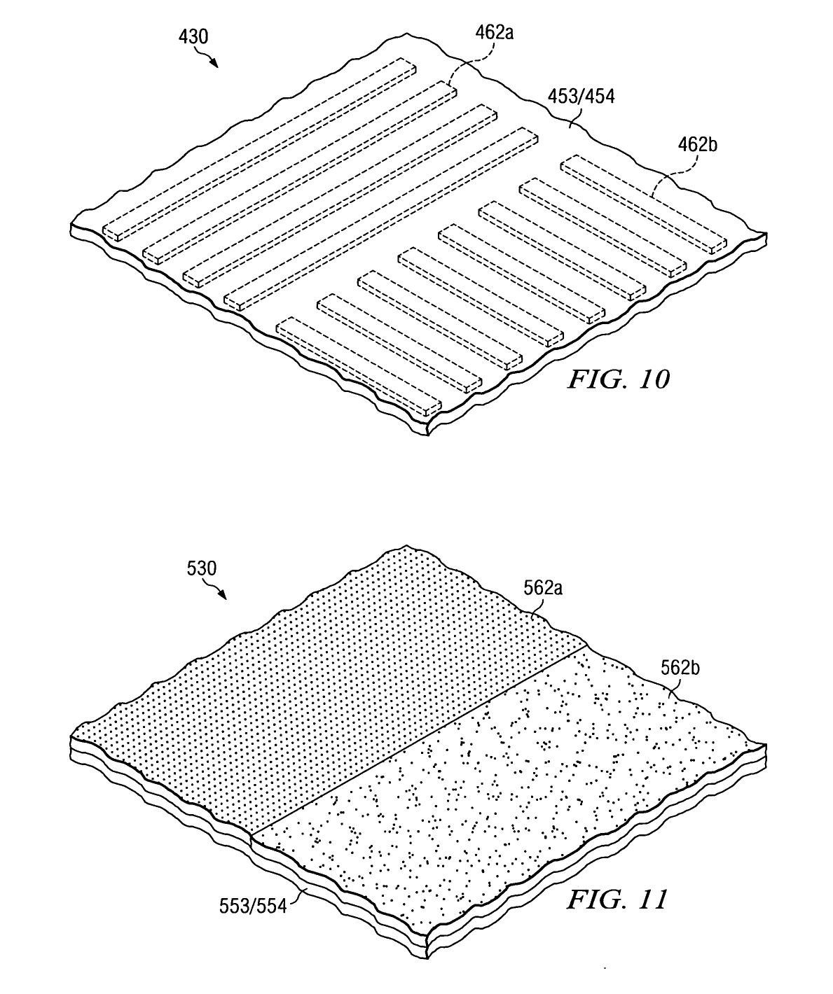

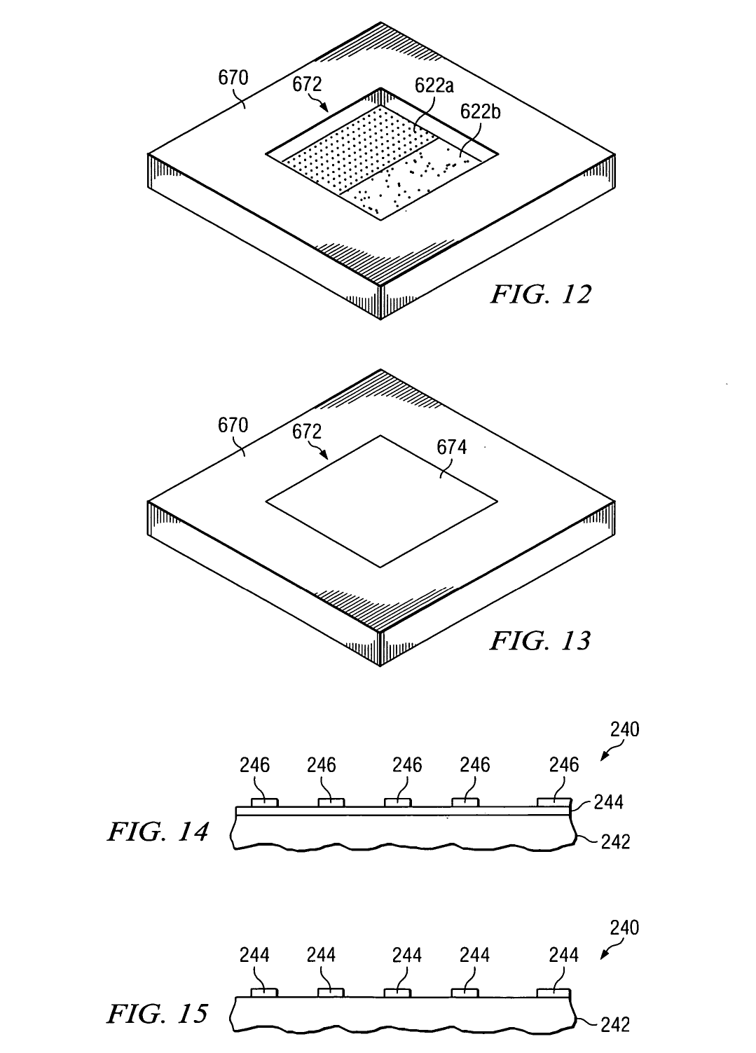

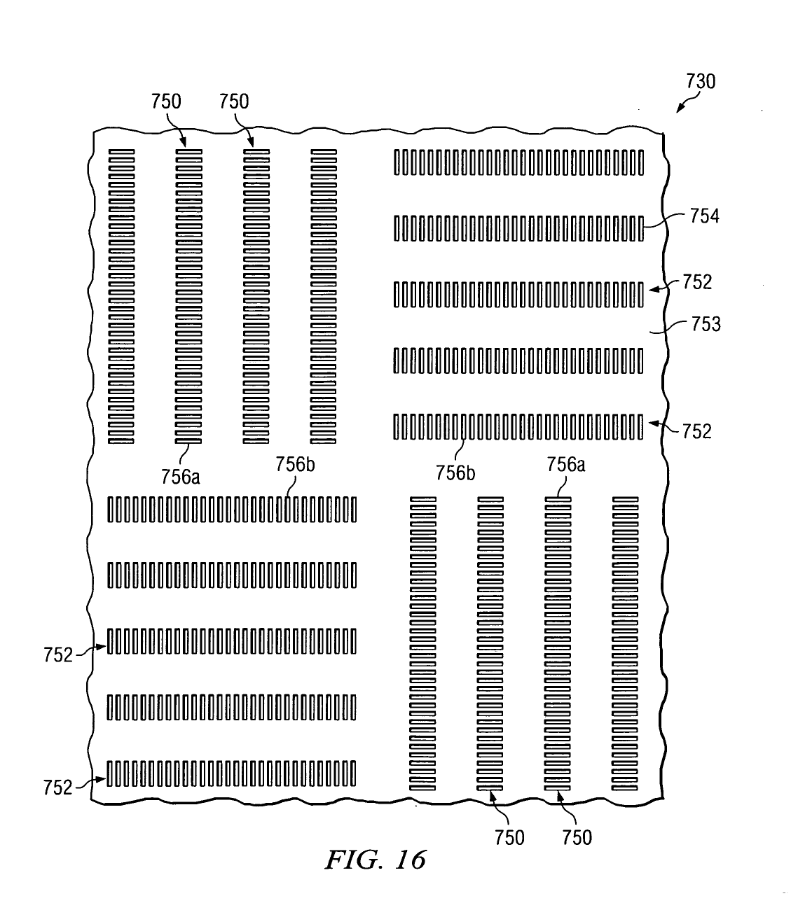

Advantageously, the novel lithography masks 230 shown in FIGS. 3 and 4 (and also mask 330 shown in FIGS. 6 through 8, mask 430 shown in FIGS. 9 and 10, mask 530 shown in FIG. 11, mask 730 shown in FIG. 16, and pellicle 670 shown in FIGS. 12 and 13 of embodiments of the present invention to be described further herein) do not require the use of polarized light in the lithography system, and thus, a polarizer 226 is not required. The polarization element or elements of the lithography masks 230, 330, 430, 530, 730, and pellicle 670 may provide all of the polarization needed for the lithography process. Alternatively, a polarizer 226 may be used, and the polarizer element or elements of the lithography masks 230, 330, 430, 530, 730, and pellicle 670 may be used to alter, reflect, absorb, or convert the polarization or filter the polarization of the light emanating from the polarizer 226 in predetermined regions, for example.

The lithography system 220 may comprise a lithography system that utilizes ultraviolet (UV) or extreme UV (EUV) light, an optical lithography system, an x-ray lithography system, an interference lithography system, or an immersion lithography system, in accordance with embodiments of the present invention, as examples, although alternatively, other types of lithography systems 220 may also be used. The lithography system 220 may comprise a stepper a step-and-scan apparatus, wherein the stage 234 is adapted to move the semiconductor device 240 while the mask 230 is moved in the exposure process, for example.

FIG. 4 illustrates a top view of a novel lithography mask 230 in accordance with a preferred embodiment of the present invention. The lithography mask 230 preferably comprises a pattern 250 or 252 for at least one feature, and at least one polarizing element 256a and 256b, as shown. The polarizing elements 256a and 256b are also referred to herein as polarizing means, polarizing gratings, or polarizing apertures herein, for example. The mask 230 may comprise a substantially transparent material 254 such as quartz, and a substantially opaque material 253 such as chrome coupled to the substantially transparent material 254. The substantially opaque material 253 may comprise MoSi or other materials having different transmission properties in magnitude and phase than the substantially transparent material 254, for example, although other materials may also be used. The substantially opaque material 253 may comprise a first pattern for at least one first feature 250 in a first region, e.g., on the left side of the mask 230 shown in FIG. 4, and a second pattern for at least one second feature 252 in at least one second region, e.g., on the right side of the mask 230 in FIG. 4.

The mask 230 includes a first polarizing means 256a in the first region, the first polarizing means 256a being adapted to polarize energy directed at the lithography mask 230 in the first region to a first type of polarization. The mask 230 includes at least one second polarizing means 256b in the at least one second region, the at least one second polarizing means 256b being adapted to polarize the energy directed at the lithography mask 230 in the at least one second region to at least one second type of polarization, the at least one second type of polarization being different than the first type of polarization. Only two regions are shown in FIG. 4; however, there may be two or more regions having features oriented in different directions, e.g., horizontally, vertically, or other directions, for example, not shown.

In the embodiment shown in FIG. 4, the polarizing elements or polarizing means comprise a plurality of gratings 256a within the patterns 250 for the first features (comprising vertical features, as shown) in the left region of the mask 230. For example, each patterns 250 for the features to be formed on a device (such as device 240 shown in FIG. 4) comprise a plurality of gratings or small lines formed within the opaque material 253 of the mask 230 arranged generally in the shape of the desired feature. Alternatively, in other embodiments, the polarizing elements or means may comprise a grating proximate the patterns for the features as shown in FIG. 6, a polarizing material proximate the patterns for the features as shown in FIGS. 9 and 10, a polarizing material proximate the entire region the features are formed in as shown in FIG. 11, or a plurality of apertures formed within the opaque material 253, as shown in FIG. 16, for example, to be described further herein.

Referring again to FIG. 4, the plurality of gratings 256a preferably comprise many small lines of opaque material 253 extending in a direction perpendicular to the patterns for the vertical features 250, as shown. The plurality of gratings 256a are adapted to provide polarization for energy directed through the patterns 250 for the first features, yet the plurality of gratings 256a are preferably too small to be printed on a semiconductor device, for example. Likewise, the polarizing elements 256b comprise a plurality of gratings 256b within the patterns 252 for the second features (comprising horizontal features, as shown) in the right region of the mask 230. The plurality of gratings 256b extend vertically within the patterns 252 and preferably comprise many small lines of opaque material 253 that are adapted to provide polarization for energy directed through the patterns 252 for the second features. The plurality of gratings 256b is preferably too small to be printed on a semiconductor device, for example.

In one embodiment, the lithography mask 230 is adapted to be used to pattern a semiconductor device using energy 224 (see FIG. 3) having a first wavelength, such as about 193 nm, as an example, although other wavelengths of light or energy may also be used. The first polarizing means 256a or the second polarizing means 256b may comprise a plurality of gratings having a first width, wherein the plurality of gratings are spaced apart by a second width. The second width may be substantially the same as the first width, for example. In this embodiment, the first width of the gratings 256a and 256b and the second width of the spaces between the gratings 256a and 256b preferably comprise about one-quarter or less of the first wavelength. For example, if the first wavelength comprises about 193 nm, the width of the gratings 256 and 256b preferably comprises about 48 nm.

In the embodiment shown in FIG. 4, the patterns for the features 250 and 252 comprise gratings 256a and 256b, respectively, so that the patterns for the features 250 and 252 will function as polarizing grids or gratings. Alternatively, the patterns for features 250 and 252 may comprise a plurality of apertures within the opaque material, as shown in FIG. 16, to be described further herein.

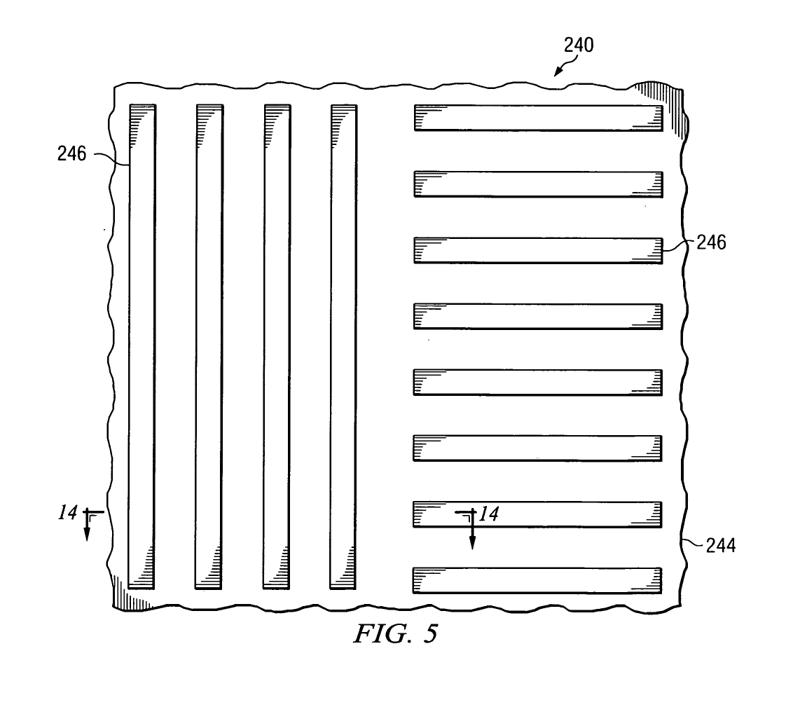

FIG. 5 shows a top view of a semiconductor device 240 or integrated circuit patterned using the lithography mask 230 shown in FIG. 4. The semiconductor device 240 or circuit includes a workpiece 242 (not shown in FIG. 5; see FIG. 3). The workpiece 242 may include a semiconductor substrate comprising silicon or other semiconductor materials covered by an insulating layer, for example. The workpiece 242 may also include other active components or circuits, not shown. The workpiece 242 may comprise silicon oxide over single-crystal silicon, for example. The workpiece 242 may include other conductive layers or other semiconductor elements, e.g., transistors, diodes, etc. Compound semiconductors, GaAs, InP, Si/Ge, or SiC, as examples, may be used in place of silicon. The workpiece 242 may comprise a silicon-on-insulator (SOI) substrate, for example.

The workpiece 242 may comprise a first orientation and at least one second orientation. In some embodiments, the first orientation and a second orientation may comprise a vertical direction and/or a horizontal direction, the horizontal direction being substantially perpendicular to the vertical direction, for example. The vertical direction and the horizontal direction comprise directions on a planar surface of the workpiece 242, for example, that are substantially perpendicular to one another. The first orientation and the at least one second orientation may comprise other non-perpendicular directions and may comprise three or more directions, for example, not shown.

In a preferred embodiment, a method of fabricating the semiconductor device 220 includes first, providing the workpiece 242. A material layer 244 to be patterned is deposited over the workpiece 242. The material layer 244 may comprise a conductive, insulative, or semiconductive material, or combinations thereof, as examples. In some embodiments, the material layer 244 preferably comprises a semiconductive material such as silicon or polysilicon, for example, although other materials may also be used. In an embodiment where transistors are formed, the material layer 244 may comprise a gate dielectric material comprising an insulator and a gate material formed over the gate dielectric material, for example.

A layer of photosensitive material 246 is deposited over the material layer 244. The layer of photosensitive material 246 may comprise a photoresist, for example. The layer of photosensitive material 246 is patterned using the lithography mask 230 to form a latent pattern for the plurality of features to be formed in the material layer 244. The layer of photosensitive material 246 is developed, as shown in FIG. 5 in a top view and also in FIG. 14 in a cross-sectional view. Later, the layer of photosensitive material 246 is used as a mask while the material layer 244 is etched using an etch process, forming a plurality of features in the material layer 244, as shown in a cross-sectional view in FIG. 15.

FIG. 6 illustrates a top view of a lithography mask 330 in accordance with another preferred embodiment of the present invention. FIGS. 7 and 8 show cross-sectional views of the lithography mask 330 shown in FIG. 6. Like numerals are used for the various elements that were described in the previous figures, and to avoid repetition, each reference number shown in FIGS. 6 through 8 is not described again in detail herein. Rather, similar materials x30, x50, x52, x54, etc. . . . are preferably used for the various material layers shown as were described for FIGS. 3 and 4, where x=2 in FIGS. 3 and 5 and x=3 in FIGS. 6 through 8, for example.

In this embodiment, the polarizing elements or means 356a and 356b comprise a plurality of gratings or apertures proximate the pattern for the features 350 and 352, respectively. The space between the patterns for the features 350 and 352 is structured to be printed with gratings or apertures 356a and 356b, (features 350 and 352 comprise gratings in FIG. 6, for example; see FIG. 16 for a polarizing means comprising apertures) so that the spaces between the patterns for the features 350 and 352 function as polarizing grids. FIG. 7 shows a cross-sectional view of a portion of the mask 330 along the gratings 356a, and FIG. 8 shows a cross-sectional view of a portion of the mask 330 between two horizontal rows of the polarizing gratings 356a. The patterns for the vertical features 350 may comprise a width 358, and the apertures 356a may comprise a width 360, as shown. The widths 358 and 360 may comprise a dimension of about 100 nm or less, as examples, although widths 358 and 360 may alternatively comprise other dimensions.

FIG. 9 shows a top view of a lithography mask 430 in accordance with yet another preferred embodiment of the present invention. Again, like numerals are used for the various elements that were described in the previous figures, and to avoid repetition, each reference number shown in FIG. 9 is not described again in detail herein. The lithography mask 430 comprises a first region such as the left region shown in FIG. 9, and the pattern for at least one feature 450 is formed in the first region. The polarizing element in this embodiment comprises a polarizing material 462a disposed in the first region of the lithography mask. The polarizing material 462a may comprise a polymer, glass, a birefringent material, or a grating polarizer, as examples, although other materials may also be used. For example, the polarizing material 462a may comprise a polymer, a glass such as CaF, or other birefringent materials. If the polarizing material 462a comprises a grating polarizer, the grating polarizer 462a preferably comprises a plurality of apertures or grating formed in a metal, such as chrome, that may be bonded to the opaque or transparent materials 453/454 of the mask 430, for example, although the grating polarizer 462a may alternatively comprise other materials.

The lithography mask 430 may comprise a second region such as the right region shown in FIG. 9, and the pattern for at least one feature 452 is formed in the second region. The polarizing element in this embodiment may comprise a polarizing material 462b disposed in the second region of the lithography mask. The polarizing material 462b may comprise a similar material as described for polarizing material 462a, for example. If features in the first and second region are oriented differently, the polarizing materials 462a and 462b are preferably different or have different properties to achieve a desired polarization in each region. For example, polarizing material 462a may be adapted to polarize light in a direction 464 parallel to the pattern for vertical features 450, and polarizing material 462b may be adapted to polarize light in a direction 466 parallel to the pattern for horizontal features 452, as shown.

In some embodiments, the mask blank used to manufacture the lithography mask 430 may have polarizing coatings disposed thereon that comprise the polarizing materials 462a and 462b. The polarized coatings 562a and 562b may be disposed globally over the first and second region, as shown in FIG. 11 in a perspective view at 530.

Alternatively, the polarizing material 462a and 462b may be disposed locally proximate the patterns for the features 450 and 452, e.g., between the patterns for the features 450 and 452, respectively, as shown in FIG. 9 in a top view and in a perspective view in FIG. 10. In these embodiments, the polarizing material 462a and 462b may be deposited and patterned to be disposed between or proximate the patterns for the features 450 and 452, respectively, as shown.

The polarizing materials 462a, 462b, 562a, and 562b may be formed on a front side or a back side of a lithography mask 430, as shown in FIGS. 10 and 11. For example, when used in the lithography system 220 shown in FIG. 3, the polarizing materials 462a, 462b, 562a, and 562b may be disposed on the front side of the lithography mask 430 or 530 that is positioned to face the illuminator 222, as shown disposed on a top face of the mask 530 in FIG. 11. Alternatively, the polarizing materials 462a, 462b, 562a, and 562b may be disposed on the back side of the lithography mask 430 or 530 that is positioned to face the projection lens system 232, as shown disposed on a bottom face of the mask 430 in FIG. 10. Note that in FIGS. 10 and 11, the opaque material and transparent material of the masks 430 and 530 are collectively shown as 453/454 and 553/554, respectively.

Embodiments of the present invention may be implemented in pellicles or other structures used protect lithography masks. Pellicles are often used in lithography to protect lithography masks from particles and contamination, for example. FIG. 12 shows a perspective view of a pellicle 670 adapted to protect a lithography mask 674 from contamination in accordance with an embodiment of the present invention. FIG. 13 shows the pellicle 670 illustrated in FIG. 12 protecting a lithography mask 674.

The pellicle includes a protection region 672 for the lithography mask 674, and at least one polarization element 622a and/or 622b adapted to polarize energy directed at the lithography mask 674 in a predetermined type of polarization proximate the protection region 672 for the lithography mask 674. The protection region 672 may be round, square, or other shapes, for example. The protection region 672 may include a membrane adapted to protect the lithography mask 674, for example, that is substantially transparent.

The lithography mask 674 may comprise a first region and at least one second region, not shown. The at least one polarization element may comprise a first polarization element 662a adapted to polarize energy directed at the lithography mask 674 in a first type of polarization and at least one second polarization element 662b adapted to polarize energy directed at the lithography mask 674 in at least one second type of polarization. The second type of polarization may be different than the first type of polarization. Preferably, in this embodiment, when a lithography mask 674 attached to the protection region 672 of the pellicle 670, the first polarization element 662a is proximate the first region of the lithography mask, and the at least one second polarization element 662b is proximate the at least one second region of the lithography mask.

In another embodiment, the at least one polarization element 622a and/or 622b is preferably fixedly attached to the lithography mask and/or pellicle 670. Thus, when the lithography mask 674 and/or the pellicle 670 is moved, the at least one polarization element 622a and/or 622b remains fixed relative to the patterns of features on the lithography mask 674, for example.

FIG. 14 shows a cross-sectional view of a semiconductor device 240 with a layer of photosensitive material 246 disposed thereon that has been patterned using one of the novel lithography masks 230, 330, 430, 530 or pellicles 670 described herein, and FIG. 15 shows the semiconductor device of FIG. 14 after the layer of photosensitive material 246 has been used to pattern a material layer 244 of the semiconductor device 240 and then removed. Embodiments of the present invention include semiconductor devices 240 patterned using the novel methods, masks, systems, and pellicles described herein.

FIG. 16 illustrates a top view of a lithography mask 730 in accordance with another embodiment of the present invention. In this embodiment, the polarizing means 756a and 756b comprise a plurality of apertures formed in the opaque material 753 of the mask 730. Furthermore, in this embodiment, two regions of patterns for vertical features 750 have polarizing elements 756a disposed within the patterns, and two regions of patterns for vertical features 752 have polarizing elements 756b disposed within the patterns. Advantageously, regions having different polarization effects may be placed in any position of the lithography mask 730, in accordance with embodiments of the present invention, e.g., in ordered regions on the mask 730 or in arbitrary positions on the mask 730. The polarizing means of other embodiments of the invention described herein may also comprise a plurality of apertures 756a and 756b, for example.

The polarization means or elements 256a, 256b, 356a, 356b, 462a, 462b, 562a, 562b, 662a, 662b, 756a, and 756b described herein allow for more customized control of polarization in arbitrary areas and parts of a lithography mask or pellicle, for example. Any desired numbers of directions of polarization e.g., two, three or more, may be achieved locally or globally in regions of lithography masks and pellicles. The polarization means or elements 256a, 256b, 356a, 356b, 462a, 462b, 562a, 562b, 756a, and 756b are aligned to features of the lithography masks when the masks are manufactured, or the polarization means or elements 662a and 662b of pellicles are aligned to the masks when the masks are installed on or attached to the pellicle, which avoids requiring an additional scanning controller or scanning operation to control the polarization, for example.

Embodiments of the present invention also include lithography systems 220 such as the one shown in FIG. 3 that utilize or include the lithography masks 330, 430, 530, or 730 shown in FIGS. 3, 4, 6, 9, 10, 11, and 16, as examples. Embodiments of the present invention also include lithography systems that utilize or include the pellicles 670 shown in FIGS. 12 and 13, for example.

Embodiments of the present invention may be used in lithography processes that utilize positive or negative photoresists, for example.

Embodiments of the present invention further include methods of patterning semiconductor devices, comprising providing a workpiece having a layer of photosensitive material disposed thereon, providing a lithography mask including a pattern for a plurality of features and a polarizing element, and exposing the layer of photosensitive material to energy using the lithography mask as a mask, forming the features in the layer of photosensitive material. The polarizing element polarizes the energy proximate pattern for the plurality of features. The layer of photosensitive material is then developed.

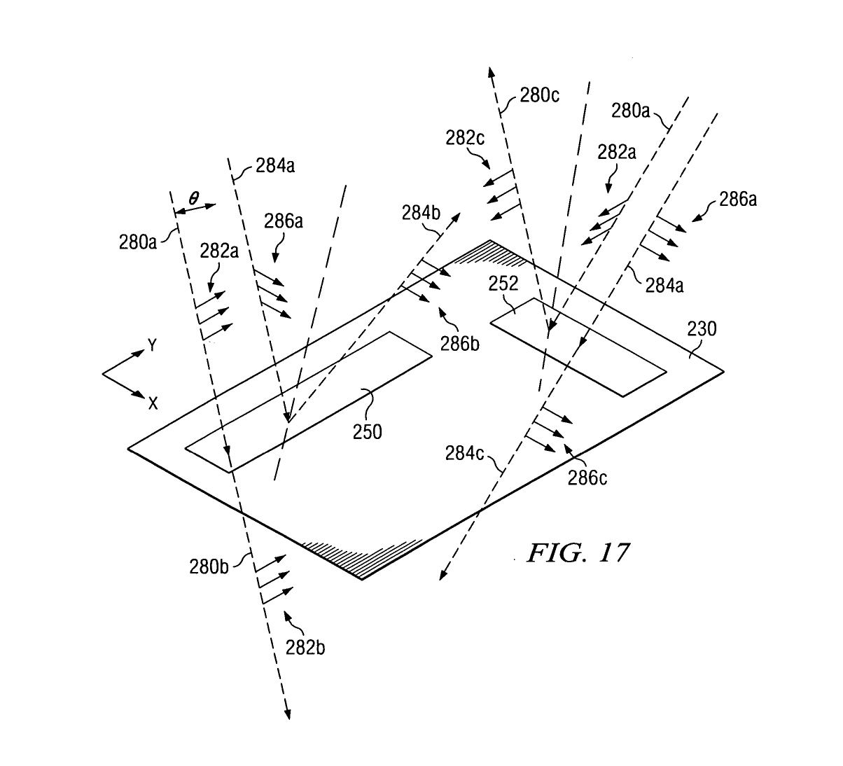

FIG. 17 shows a perspective view of the lithography mask 230 shown in FIG. 4 in accordance with a preferred embodiment of the present invention, illustrating the effect of the novel lithography mask 230 on energy or light 280a and 284a that is directed towards the lithography mask 230. In an example where polarized light 280a and 284a is used in an exposure process, for example, the polarized light 280a or 284a is used to globally illuminate the mask 102, generally from two directions using a single dipole illumination (e.g., 280a is shown impinging the mask 230 from the left and the right at angle θ). Because of the novel polarizing elements (see 256a and 256b in FIG. 4) of the patterns for the vertical and horizontal features 250 and 252, respectively, selective polarization of the light 280a or 284a for the patterns 250 and 252 is achieved.

For example, if light 280a polarized in the y direction 282a is used in the exposure process to pattern a semiconductor device, the light 280a is allowed to pass through the patterns for the vertical features 250 in the mask 230, as shown at 280b having polarization state 282b in the y direction. However, light 280a impinging upon the patterns for the horizontal features 252 is directed away from the mask 230, as shown at 280c and 282c.

Similarly, if light 284a polarized in the x direction 286a is used in the exposure process to pattern a semiconductor device, the light 284a is allowed to pass through the patterns for the horizontal features 252 in the mask 230, as shown at 284c having polarization state 286c in the x direction. However, light 284a impinging upon the patterns for the vertical features 250 is directed away from the mask 230, as shown at 284b and 286b.

Thus, an exposure process using the novel mask 230 is more effective in patterning a semiconductor device and results in improved resolution and extended process latitude, leading to a more stable process. The features patterned on a semiconductor device achieve the desired dimensions, due to the self-polarizing mask 230 having polarization dependent features 250 and 252. The polarizing elements 256a and 256b of the features of the mask 250 and 252, respectively, preferably eliminate the TM waves in the imaging plane and allow the TE waves to pass through the mask 230, for example, increasing the contrast and thus the resolution of features on a semiconductor device.

In some embodiments, the polarizing element may reflect away an undesired type of polarization to achieve the desired polarization, for example, as illustrated in FIG. 17. In this embodiment, two exposures may be used, each having a different type of polarization. In other embodiments, the polarizing element may convert the energy to a desired type of polarization, e.g., by adjusting the thickness of the polarizing material such that it functions acts as a “lambda half plate,” converting the energy into the desired polarization type. In other embodiments, the undesired polarization can be absorbed or diverted to other directions, for example.

In some embodiments, a method of manufacturing a semiconductor device 240 (see FIGS. 14 and 15) using the novel lithography masks and pellicles described herein comprises using a layer of photosensitive material 246 as a mask to pattern a material layer 244 of the workpiece, forming at least one first feature and at least one second feature in the material layer 244. Forming the at least one first feature and forming the at least one second feature comprise forming the at least one first feature comprising a first dimension and forming the at least one second feature comprising a second dimension, wherein the second dimension is substantially the same as the first dimension. Exposing the layer of photosensitive material 246 to energy may comprise exposing the layer of photosensitive material 246 to polarized or unpolarized light, using one or more exposure processes.

Advantageously, regions of features may be individually customly polarized with a desired polarization, using the novel lithography masks and pellicles described herein. Features aligned in different directions of semiconductor devices may be polarized differently, for example.

Preferably, the at least one polarization element is fixedly attached to the lithography mask, e.g., the polarization elements remain stationary with respect to the lithography masks or pellicles. In some embodiments, the lithography mask or pellicle holding the lithography mask may be moved laterally during the scanning process, but preferably the polarization elements described herein remain stationary with respect to the masks and/or pellicle.

The lithography masks described herein may comprise binary masks, phase shifting masks, alternating phase shifting masks, attenuating phase shifting masks, or combinations thereof, as examples. The lithography masks may comprise bright field masks or dark field masks, for example.

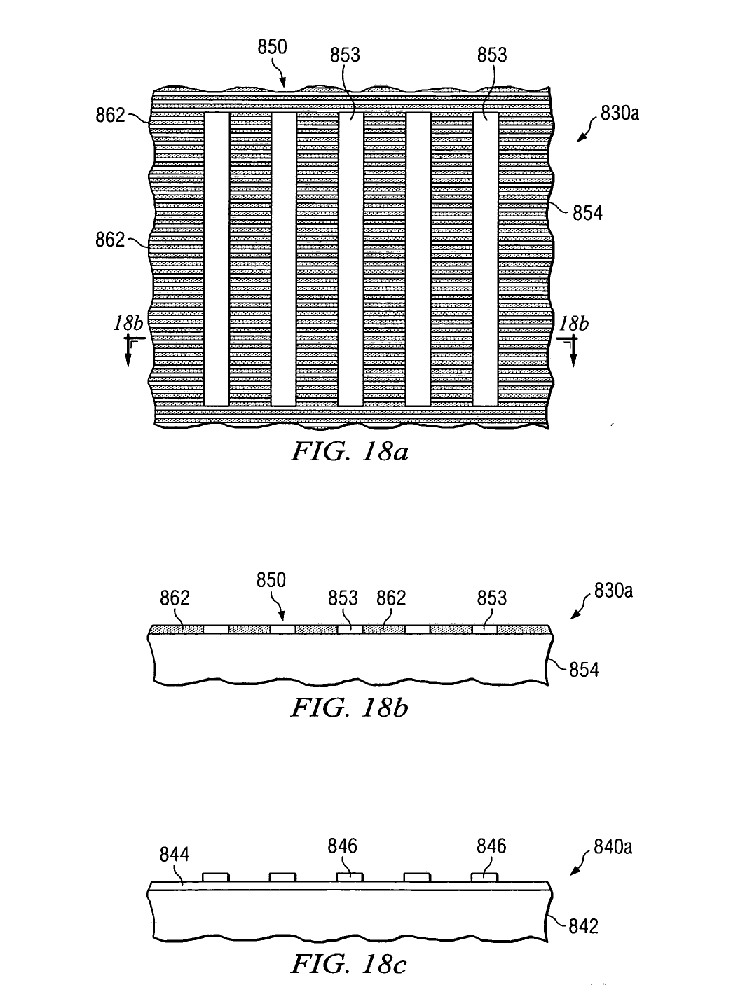

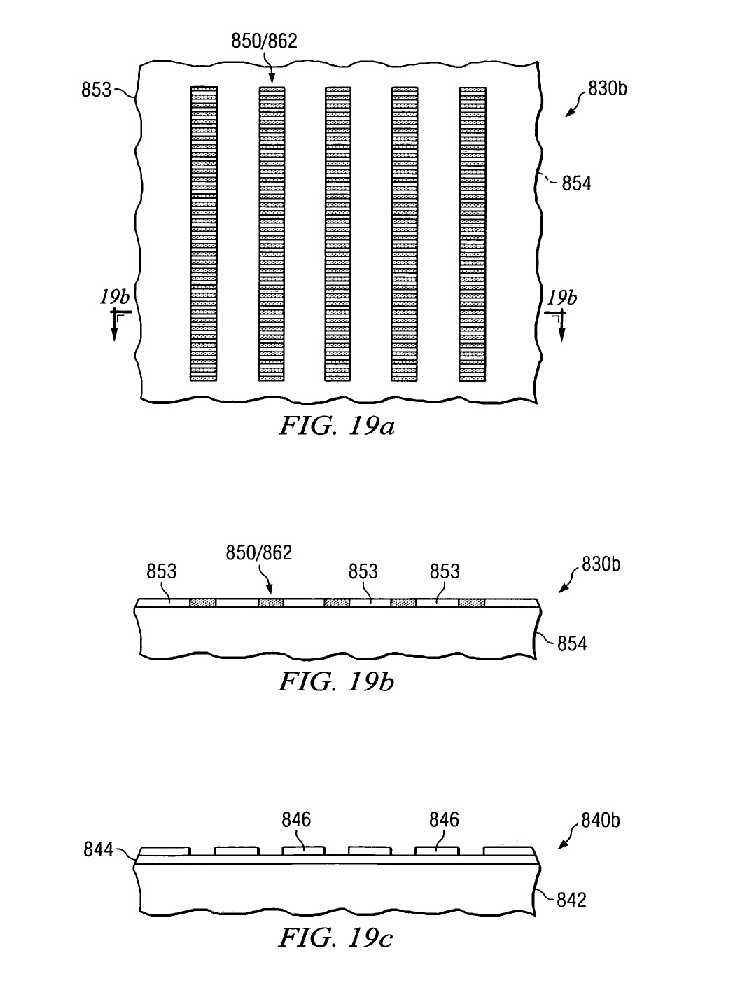

FIGS. 18a and 19a illustrate novel lithography masks 830a and 830b in accordance with embodiments of the present invention. FIGS. 18b and 19b show cross-sectional views of the masks 830a and 830b shown in FIGS. 18a and 19a, respectively. FIGS. 18c and 19c show semiconductor devices 840a and 840b that have been patterned using positive resist and the masks 830a and 830b of FIGS. 18a and 19a, respectively. Like numerals are used for the various elements that were described in the previous figures, and to avoid repetition, each reference number shown in FIGS. 18a, 18b, 18c, 19a, 19b, and 19c is not described again in detail herein.

In FIGS. 18a and 18b, the lithography mask 830a comprises a binary mask comprising a bright field mask, wherein the patterns for features 850 comprise a solid opaque pattern that appears visually as the patterns that are formed in a layer of resist 846 when the mask 830a is used to pattern the layer of positive resist 846, as shown in FIG. 18c. The mask 830a may comprise a “chrome on glass” (CoG) mask, e.g., wherein the opaque material 853 comprises chrome and wherein the transparent material 854 comprises glass, although the mask 830a may alternatively comprise other materials.

In this embodiment, regions of the mask 830a not comprising the patterns for features 850 comprise a polarizing grid 862, e.g., proximate and between the patterns for features 850. The polarizing grid 862 is adapted to polarize light or energy to an optimal polarization type for the patterns for features 850, for example. FIG. 18c shows a semiconductor device 840a comprising a positive photoresist 846 patterned using the mask 830a of FIGS. 18a and 18b.

In FIGS. 19a and 19b, the lithography mask 830b comprises a binary mask comprising a dark field mask, wherein the patterns for features 850 comprise polarizing grids 862 formed in the opaque material 853. The regions between and proximate the patterns for features 850 comprise blocked solid regions of the opaque material 853. The mask 830b may comprise a CoG mask, e.g., wherein the opaque material 853 comprises chrome and wherein the transparent material 854 comprises glass, although other materials may also be used. The polarizing grid 862 of the patterns for features 850 is adapted to polarize light or energy to an optimal polarization type for the patterns for features 850 in this embodiment, for example. FIG. 19c shows a semiconductor device 840b comprising a positive photoresist 846 patterned using the mask 830b of FIGS. 19a and 19b.

A single mask may comprise some regions that include the patterns 850 and 862 shown in FIG. 18a and other regions that comprise the patterns 850/862 shown in FIG. 19a, for example. Vertically oriented features are illustrated in FIGS. 18a and 19a; however, a single mask may also comprise other regions that are oriented horizontally or in other directions, and polarized to a type optimal for the particular patterns in those regions, for example.

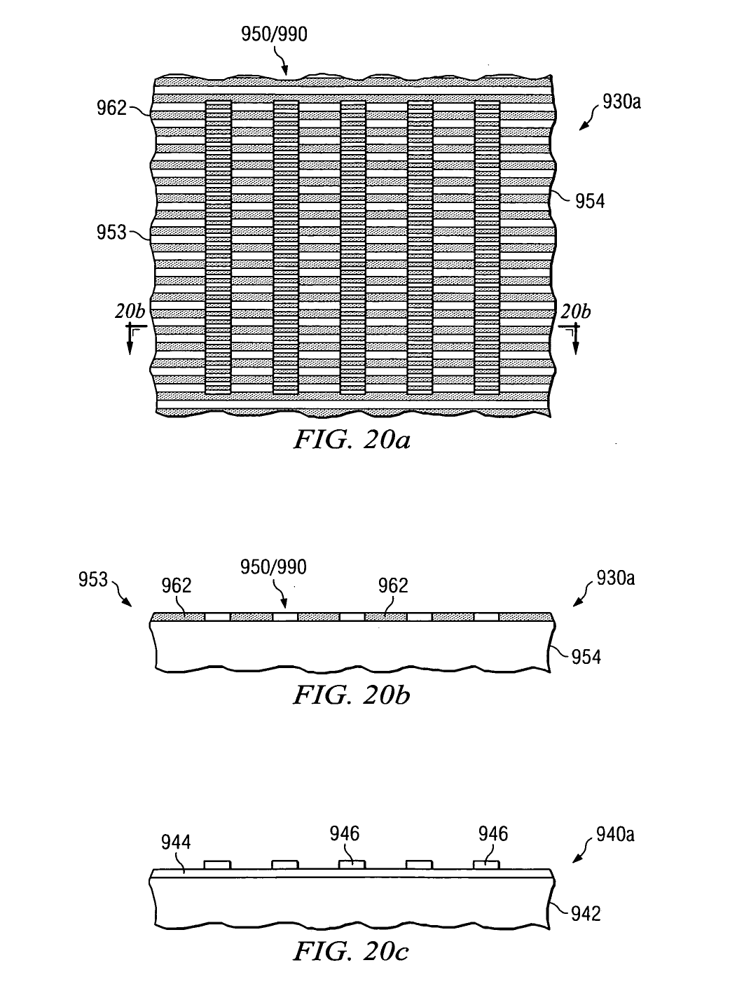

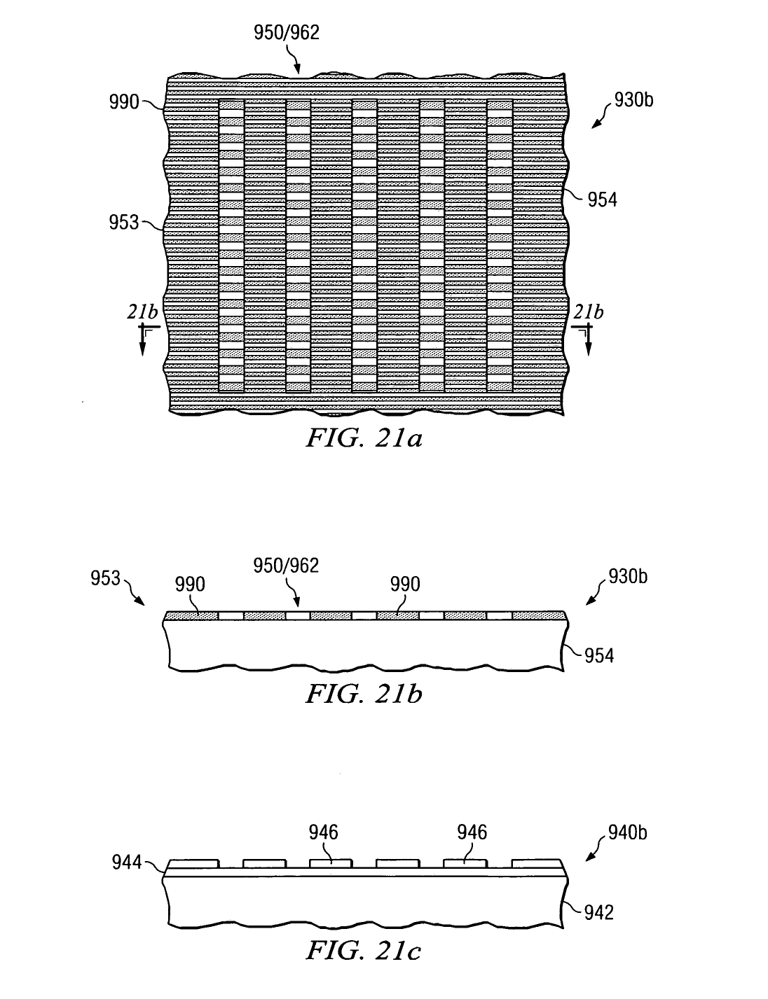

FIGS. 20a and 21a illustrate novel lithography masks 930a and 930b in accordance with embodiments of the present invention. FIGS. 20b and 21b show cross-sectional views of the masks 930a and 930b shown in FIGS. 20a and 21a, respectively. FIGS. 20c and 21c show semiconductor devices 940a and 940b that have been patterned using the masks 930a and 930b of FIGS. 20a and 21a, respectively. Again, like numerals are used for the various elements that were described in the previous figures, and to avoid repetition, each reference number shown in FIGS. 20a, 20b, 20c, 21a, 21b, and 21c is not described again in detail herein.

In FIGS. 20a and 20b, the lithography mask 930a comprises a phase shifting mask comprising a bright field mask, and the regions other than the patterns for features 950 comprise a plurality of first polarizing grids 962. The patterns for features 950 comprise a plurality of second polarizing grids 990 that are different than the plurality of first polarizing grids 962. The plurality of first and second polarizing grids 962 and 990 are formed in the opaque material 953. The plurality of first polarizing grids 962 is adapted to polarize light or energy to an optimal polarization type for the patterns for features 950, for example. The plurality of second polarizing grids 990 may be thinner and may be spaced apart by a smaller amount than the thickness and spacing of the plurality of first polarizing grids 962, for example, as shown. FIG. 20c shows a semiconductor device 940a comprising a positive photoresist 946 patterned using the mask 930a of FIGS. 20a and 20b.

In FIGS. 21a and 21b, the lithography mask 930b comprises a phase shifting mask comprising a dark field mask, wherein the patterns for features 950 comprise a plurality of first polarizing grids 962 formed in the opaque material 953. The regions between and proximate the patterns for features 950 comprise a plurality of second polarizing grids 990 formed in the opaque material 953. The plurality of first polarizing grids 962 of the patterns for features 950 is adapted to polarize light or energy to an optimal polarization type for the patterns for features 950 in this embodiment, for example. The plurality of second polarizing grids 990 assists in forming the patterns 950 in this embodiment, for example. The plurality of second polarizing grids 990 may be thinner and may be spaced apart by a smaller amount than the thickness and spacing of the plurality of first polarizing grids 962, for example, as shown. FIG. 21c shows a semiconductor device 940b comprising a positive photoresist 946 patterned using the mask 930b of FIGS. 21a and 21b.

Again, a single mask may comprise some regions that comprise the patterns 950/990 and 962 shown in FIG. 20a and other regions that comprise the patterns 950/962 and 990 shown in FIG. 21a, for example. Vertically oriented features are illustrated in FIGS. 20a and 21a; however, a single mask may also comprise other regions that are oriented horizontally or other directions, and polarized to a type optimal for the particular patterns in those regions, for example.

In the embodiments shown in FIGS. 20a, 20b, 21a, and 21b, the plurality of first polarizing grids 962 may be adapted to polarize energy impinging on the lithography masks 930a and 930b to a first type of polarization, and the plurality of second polarizing grids 990 may be adapted to polarize energy impinging on the lithography mask to a second type of polarization, wherein the second type of polarization is different than the first type of polarization, for example. In some embodiments, the plurality of first polarizing grids 962 may comprise a first material, and the plurality of second polarizing grids 990 may comprise a second material, wherein the second material is different than the first material. In yet other embodiments, the plurality of first polarizing grids 962 may comprise a first pattern of lines and spaces, and the plurality of second polarizing grids 990 may comprise a second pattern of lines and spaces, wherein the second pattern of lines and spaces is different than the first pattern of lines and spaces. For example, the lines and spaces of the plurality of first polarizing grids 962 and the plurality of second polarizing grids 990 may comprise different widths and may be spaced apart from one another by different dimensions.

Embodiments of the present invention achieve technical advantages by providing novel methods of forming features in both, a horizontal and vertical direction, or any other desired direction, for example. In CMOS applications, a reduction of negative effects of gate line-width variation may be achieved, while still maintaining the device layout in both an x and y direction, for example. The polarization dependent feature masks and pellicles increase throughput by only requiring a single exposure or a single scanning operation for each region of a semiconductor device being exposed, yet have the advantage of customized e.g., polarized illumination in two or more directions. Two or more sets of differently oriented features may be formed on the lithography masks or on a pellicle with one or more illumination and exposure directions, orientations, or polarization types. In some embodiments, horizontal features may be formed by an exposure process using one dipole exposure, and vertical features may be formed using another dipole exposure. Alternatively, both horizontal features and vertical features may be formed with a single dipole exposure, although other directionally oriented features may also be formed.

Embodiments of the present invention achieve technical advantages by providing novel lithography masks, systems, methods, and pellicles for lithography masks, and semiconductor devices, wherein a single exposure may be used to more accurately pattern features of semiconductor devices. Because a double exposure process is not required, the number of lithography masks is reduced, resulting in a cost savings. Contrast in the exposure process is improved, resulting in increased resolution and the ability to print smaller features and/or extend the process latitude of the lithographic process.

Features of semiconductor devices manufactured using the novel methods described herein may comprise transistor gates, conductive lines, vias, capacitor plates, and other features, as examples. Embodiments of the present invention may be used to pattern features of memory devices, logic circuitry, and/or power circuitry, as examples, although other types of ICs and devices may also be fabricated using the manufacturing techniques and processes described herein.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A lithography mask, comprising:
a pattern for at least one feature; and
at least one polarizing element.

2. The lithography mask according to claim 1, wherein the at least one polarizing element comprises a plurality of apertures or gratings within the pattern for the at least one feature.

3. The lithography mask according to claim 1, wherein the at least one polarizing element comprises a plurality of apertures or gratings proximate the pattern for the at least one feature.

4. The lithography mask according to claim 1, wherein the pattern for the at least one feature comprises a plurality of first polarizing grids, wherein the lithography mask further includes a plurality of second polarizing grids, and wherein the plurality of first polarizing grids or the plurality of second polarizing grids comprise the at least one polarizing element.

5. The lithography mask according to claim 4, wherein the plurality of first polarizing grids is adapted to polarize energy impinging on the lithography mask to a first type of polarization, wherein the plurality of second polarizing grids is adapted to polarize energy impinging on the lithography mask to a second type of polarization, and wherein the second type of polarization is different than the first type of polarization.

6. The lithography mask according to claim 4, wherein the plurality of first polarizing grids comprises a first material or a first pattern of lines and spaces, wherein the plurality of second polarizing grids comprises a second material or a second pattern of lines and spaces, and wherein the second material is different than the first material or wherein the second pattern of lines and spaces is different than the first pattern of lines and spaces.

7. The lithography mask according to claim 1, wherein the lithography mask comprises a first region, wherein the pattern for the at least one feature is formed in the first region, and wherein the at least one polarizing element comprises a polarizing material disposed in the first region of the lithography mask.

8. The lithography mask according to claim 7, wherein the polarizing material comprises a polymer, glass, a birefringent material, or a grating polarizer.

9. The lithography mask according to claim 7, wherein the polarizing material is disposed globally over the first region, or locally proximate the pattern for the at least one feature.

10. A lithography mask, comprising:
a substantially transparent material;
a substantially opaque material coupled to the substantially transparent material, wherein the substantially opaque material comprises a first pattern for at least one first feature in a first region and a second pattern for at least one second feature in at least one second region;
a first polarizing means in the first region, the first polarizing means being adapted to polarize energy directed at the lithography mask in the first region to a first type of polarization; and
at least one second polarizing means in the at least one second region, the at least one second polarizing means being adapted to polarize the energy directed at the lithography mask in the at least one second region to at least one second type of polarization, the at least one second type of polarization being different than the first type of polarization.

11. The lithography mask according to claim 10, wherein the lithography mask comprises a binary mask, a phase shifting mask, an alternating phase shifting mask, an attenuating phase shifting mask, a bright field mask, a dark field mask, or combinations thereof.

12. The lithography mask according to claim 10, wherein the lithography mask is adapted to be used to pattern a semiconductor device using energy having a first wavelength, wherein the first polarizing means or the at least one second polarizing means comprises a plurality of apertures or gratings having a first width, wherein the plurality of apertures or gratings are spaced apart by a second width, and wherein the first width and the second width comprise about one-quarter or less of the first wavelength.

13. The lithography mask according to claim 10, wherein the first polarizing means comprises apertures or gratings within the first pattern, apertures or gratings proximate the first pattern, a polarizing material proximate the first pattern, or a polarizing material proximate the entire first region, and wherein the at least one second polarizing means comprises apertures or gratings within the second pattern, apertures or gratings proximate the second pattern, a polarizing material proximate the second pattern, or a polarizing material proximate the entire at least one second region.

14. A lithography system including the lithography mask according to claim 10.

15. A pellicle for a lithography mask, comprising:
a protection region for the lithography mask; and
at least one polarization element adapted to polarize energy directed at the lithography mask in a predetermined type of polarization proximate the protection region for the lithography mask.

16. The pellicle according to claim 15, wherein the lithography mask comprises a first region and at least one second region, wherein the at least one polarization element comprises a first polarization element adapted to polarize energy directed at the lithography mask in a first type of polarization and at least one second polarization element adapted to polarize energy directed at the lithography mask in at least one second type of polarization, the second type of polarization being different than the first type of polarization, and wherein when a lithography mask is attached to the protection region, the first polarization element is proximate the first region of the lithography mask, and the at least one second polarization region is proximate the at least one second region of the lithography mask.

17. The pellicle according to claim 15, wherein the at least one polarization element is fixedly attached to the lithography mask.

18. A lithography system including the pellicle according to claim 15.

19. A lithography system, including:
a support for a device having a material layer to be patterned disposed thereon;
a projection lens system proximate the support for the device;
an illuminator proximate the projection lens system; and
a lithography mask disposed between the projection lens system and the illuminator, wherein the lithography mask includes at least one polarization element adapted to polarize energy directed at the lithography mask from the illuminator to a predetermined type of polarization towards the support for the device.

20. The lithography system according to claim 19, further comprising a polarizer disposed between the illuminator and the lithography mask.

21. The lithography system according to claim 19, wherein the at least one polarization element is disposed on a first side of the lithography mask facing the illuminator, or wherein the at least one polarization element is disposed on a second side of the lithography mask facing the projection lens system.

22. The lithography system according to claim 19, wherein the lithography system comprises a lithography system that utilizes ultraviolet (UV) or extreme UV (EUV) light, an optical lithography system, an x-ray lithography system, an interference lithography system, or an immersion lithography system.

23. A method of patterning a device, the method comprising:
providing a workpiece having a layer of photosensitive material disposed thereon;
providing a lithography mask including a pattern for a plurality of features and a polarizing element;
exposing the layer of photosensitive material to energy using the lithography mask as a mask, forming the features in the layer of photosensitive material, wherein the polarizing element is adapted to polarize the energy proximate the pattern for the plurality of features; and
developing the layer of photosensitive material.

24. The method according to claim 23, wherein the polarizing element reflects, diverts, or absorbs an undesired type of polarization of the energy, wherein the polarizing element converts the energy to a desired type of polarization, and/or wherein the polarizing element permits the energy to pass through the lithography mask.

25. The method according to claim 23, further comprising using the layer of photosensitive material as a mask to pattern a material layer of the workpiece, forming at least one first feature and at least one second feature in the material layer, wherein forming the at least one first feature and forming the at least one second feature comprise forming the at least one first feature comprising a first dimension and forming the at least one second feature comprising a second dimension, wherein the second dimension is substantially the same as the first dimension.

26. The method according to claim 25, wherein the at least one first feature is aligned in a first direction of the device, and wherein the at least one second feature is aligned in a second direction of the device, the second direction being different than the first direction.

27. The method according to claim 23, wherein providing the lithography mask comprises providing a lithography mask including a pattern for the at least one first feature in a first region and a pattern for the at least one second feature in a second region, wherein the polarizing element comprises a first polarizing element in the first region and a second polarizing element in the second region, the first polarizing element being adapted to polarize the energy in a first type of polarization, and the second polarizing element being adapted to polarize the energy in a second type of polarization, the second type of polarization being different than the first type of polarization.

28. The method according to claim 23, wherein exposing the layer of photosensitive material to energy comprises exposing the layer of photosensitive material to polarized or unpolarized light.

29. A device manufactured in accordance with the method of claim 23.
